(19) United States
(12) Patent Application Publication
(10) Pub. No.: US 2008/0319693 A1
(43) Pub. Date: Dec. 25, 2008

(54) Method, Device And Computer Program For Evaluating A Signal Transmission

(75) Inventors: Wolfgang Spirkl, Germering (DE); Holger Steffens, Munich (DE)

Correspondence Address: LAWRENCE Y.D. HO & ASSOCIATES PTE LTD, 30 BIDEFORD ROAD, #02-02, THONGSIA BUILDING, SINGAPORE, 229922, SG

(73) Assignee: Qimonda AG, Munchen (DE)

(21) Appl. No.: 11/764,811

(22) Filed: Jun. 19, 2007

(51) Int. Cl. G01R 25/00; G01R 29/00

(52) U.S. Cl. 702/79; 702/57

(57) ABSTRACT

A method comprises the step of obtaining a first signal of the signal from a first position of a transmission channel, and a second signal of the signal from a second position of the transmission channel, determining a delay time between the first signal and the second signal by a first degree of alikeness of the first signal and the second signal trace, and determining a direction function vector of the signal by a second degree of alikeness of the first signal and the second signal trace.

### FIELD OF TECHNOLOGY

The application relates to evaluation of characteristics of signal transmission.

### BACKGROUND

A transmission line acts as a conduit for transmission of signals between the ends of the transmission line.

### BRIEF DESCRIPTION OF THE DRAWINGS

FIG. 1 illustrates an overview flow chart of methods to evaluate signal transmission;

FIG. 2 illustrates a unidirectional communication system;

FIG. 3 illustrates graphs of signals of the unidirectional communication system of FIG. 2;

FIG. 4 illustrates a graph of a full cross-correlation R of the signals of FIG. 3;

FIG. 5 illustrates a bidirectional communication system;

FIG. 6 illustrates graphs of signals of the bidirectional communication system of FIG. 5;

FIG. 7 illustrates a full cross-correlation graph R of the signals of FIG. 6;

FIG. 8 illustrates digitized signals of a third embodiment of the method;

FIG. 9 illustrates the digitized signals of FIG. 8, a modified digitized signal graph, and a moving cross-correlation with window graph K;

FIG. 10 illustrates the digitized signal of FIG. 8 and a direction function graph M; and

FIG. 11 illustrates graphs of further signals of the bidirectional communication system of FIG. 5;

FIG. 12 illustrates graphs of further signals of the bidirectional communication system of FIG. 5;

FIG. 13 illustrates a full cross-correlation graph R of the signals of FIG. 12;

FIG. 14 illustrates a zoomed view of the full cross-correlation graph R of FIG. 13;

FIG. 15 illustrates moving cross-correlation with window graphs K of the signals of FIG. 12;

FIG. 16 illustrates direction function graphs M of the signals of FIG. 12; and

FIG. 17 illustrates a computer system for evaluating characteristics of signal traces.

### DETAILED DESCRIPTION

In the following description, details are provided to describe embodiments of the application. It shall be apparent to one skilled in the art, however, that the embodiments may be practised without such details.

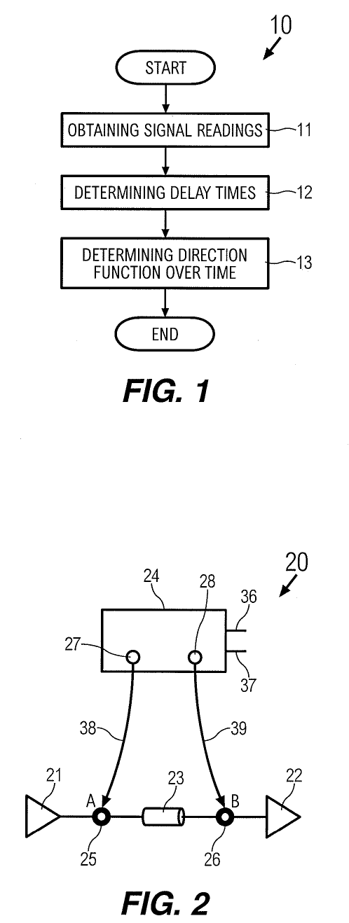

FIG. 1 illustrates an overview flow chart 10 of an example of a method to determine characteristics of a signal transmission.

The method comprises a step 11 of obtaining signal readings or signals of a signal or of multiple signals. The signals may be electrical readings of the signal and they are obtained from two or more different positions of a predetermined transmission line. The expressions “signal reading” and “signal trace” are synonyms for a detected signal here and in the description of the following embodiments.

Examples of such a transmission line are a signal line between a memory module such as a Double Data Rate (DDR) memory module or a Graphic Double Data Rate (GDDR) module, and an external control module for the memory module. Such transmission lines are often operated without additional hardware handshake lines which provide information about the direction of a signal on the transmission line. Further examples are transmission lines in signal processing systems, in communication systems and in data transmission systems such as video processing systems.

A step 12 of determining delay times of the signal is provided after the step 11. The step 12 of determining delay times of the signal is performed by evaluating a degree of alikeness R between the signal traces.

A step 13 of determining a direction function M over time is performed after the step 12. The step 13 of determining the direction function M over time is performed by evaluating a degree of alikeness K between the signal traces.

In a broad sense, the signals may be in analog form or in digital form. The direction function M of multiple signals may show a direction of each signal.

The steps 11, 12, and 13 will be explained with reference to following exemplary embodiments. Steps 11, 12, and 13 are not necessarily comprised in one single embodiment. Examples may comprise step 11 and step 12 or step 11 and step 13, especially when the delay times of the signal of step 12 do not vary over consecutive evaluations. A further example may comprise steps 11, 12, and 13 in one single embodiment.

FIGS. 2 to 4 illustrate an embodiment of a method to determine characteristics of a signal transmission.

FIG. 2 shows an example of a unidirectional communication system 20 that includes a transmitter 21, a receiver 22, a transmission line 23 and a measuring instrument 24.

The transmission line 23 has a first end and a second end. The first end is connected to the transmitter 21 whilst the second end is connected to the receiver 22. A first signal observation point (A) 25 is chosen at a first section of the transmission line 23 whilst a second signal observation point (B) 26 is chosen at a second section of the transmission line 23. The first signal observation point (A) 25 and the second signal observation point (B) 26 are provided as electrical contact points.

The measuring instrument 24 comprises a plurality of inputs 27 and 28 and a plurality of outputs 36 and 37. The input 27 is connected to the first signal observation point (A) 25 by a probe 38 whilst the input 28 is connected to the second signal observation point (B) 26 by a probe 39.

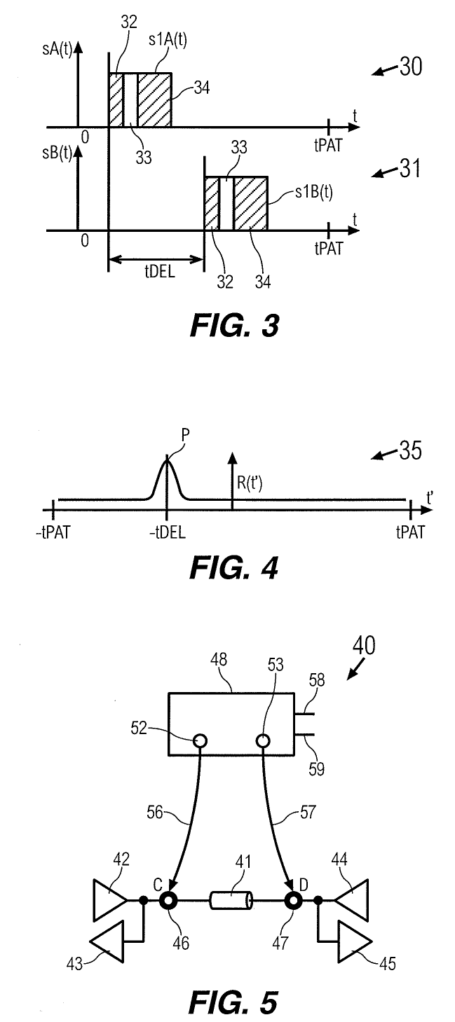

FIG. 3 illustrates graphs of signals of the unidirectional communication system 20 of FIG. 2. The FIG. 3 shows a first signal 30 taken at the first signal observation point (A) 25 and a second signal 31 taken at the second signal observation point (B) 26 as observed by the measuring instrument 24.

The first signal graph 30 extends from 0 time-point to tPAT time-point and it shows a signal sA(t) over time. In comparison, the second signal graph 31 extends from 0 time-point to tPAT time-point and shows a signal sB(t) line over time.

The signal sA(t) comprises a signal s1A(t) whilst the signal sB(t) comprises a signal s1B(t). The shape of the signal s1A(t) is similar to the shape of the signal s1B(t). Relative to the signal s1A(t), the signal s1B(t) as provided is delayed by a delay time of tDEL. Therefore, the signals s1A(t) and the s2B(t) are essentially identical, comprising a time shift tDEL.

In this embodiment, the signal s1A(t) is generated when a data package is transmitted over the transmission line 23 from the transmitter 21 to the receiver 22. The data package comprises a header 32, a package body 33 and a package limiter 34, which are shown as dotted or darker and un-dotted or brighter areas under the signal s1A(t) as observed at the signal observation point (A) 25. The same data package is observed at the signal observation point (B) 26, which is depicted by similar dotted or darker and un-dotted or brighter areas under the signal s1B(t).

The shape of the signal s1A(t) is similar to the shape of the signal s1B(t). Relative to the signal s1A(t), the signal s1B(t) as provided is delayed by a delay time of tDEL. Therefore, the signals s1A(t) and the s2B(t) are essentially identical, comprising a time shift tDEL.

FIG. 4 illustrates a graph 35 of a full cross-correlation R(t′) of the signals sA(t) and sB(t) of FIG. 3 as produced by the output 36 of the measuring instrument 24. The graph 35 extends from −tPAT time point to tPAT time point, and it shows a signal comprising horizontal lines with a peak P at −tDEL time point.

The horizontal line is usually interpreted as showing non-correlation between the signals sA(t) and sB(t). In application, the non-correlation may also appear as a line that is close to the horizontal line because of noise or modulation. For example, a bit-rate of digital signals may modulate an amplitude of the full cross-correlation R(t′).

The transmission line 23 is a form of a transmission channel. The transmission line 23 can be in a form of an electrical conductor or in a form of a wire or conductive trace. The transmitter 11 or the receiver 12 may be a part of an electrical circuit. The electrical circuit may in turn be part of a semiconductor device. The transmitter 11 or the receiver 12 may also be part of a transceiver.

In a broader sense, the characteristics of the signal s1B(t) may be different from the characteristics of the signal s1A(t). The signal s1B(t) may be degraded after travelling along the transmission line 41 so that it may comprise jitter or noise or it may be attenuated or it may be deformed in another way.

The signals s1A(t) and s1B(t) may be in the form of an arbitrary signal, different from the signal of a data package as described above. The data packages may be in a form that is without the header 32 and the package limiter 34. For example, the data packages of Double Data Rate (DDR) signals or of Graphic Double Data Rate (GDDR) signals may be without the header 32 and the package limiter 34. The signals s1A(t) and s1B(t) can be a form of electrical voltage or current or a form of electromagnetic waves such as visible light.

The example can be applied to a measurement system with three or more inputs for evaluation of three or more signal observation points. The calculation to determine the full cross-correlation R(t′) may be performed by the measuring instrument 24 or by another instrument.

An electrical signal, passing through a medium of dielectric constant of 4 (∈_r=4), takes about 100 ps (picoseconds) to cover a distance of 1.5 cm (centimeter).

The transmitter 11, as provided here, transmits a signal to the receiver 12. The receiver 12, as provided here, will then receive the transmitted signal. The transmission line 13, as provided here, acts as a conduit for the transmission of the signal. The first signal observation point (A) 15 or the second signal observation point (B) 16, as provided here, provides a point to observe or to probe the signal. The measuring instrument 24, as provided here, receives signals via the probes 38 and 39. The measuring instrument 24 processes the signals and sends the processed signals or data to the outputs 36 and 37 of the measuring instrument 24. The processed signals can be in the form of a full cross-correlation R of signals or in a form of a direction function M of the processed signals.

An embodiment of the method to determine a time delay of signals of a unidirectional communication system 20 comprises—according to step 11 of FIG. 1—obtaining the signal sA(t) from the first signal observation point (A) 25 and the signal sB(t) from the second signal observation point (B) 26 by the measuring instrument 24. This is illustrated in FIGS. 2 and 3.

The signals sA(t) and sB(t) are afterward—according to step 12 of FIG. 1—processed by the measuring instrument 24. The processing comprises treating the signals sA(t) and sB(t) in order to remove constant value components. The treated signals sA′(t) and sB′(t) are then calculated as shown below.

sA′(t)=sA(t)−average[sA(t)] (1)
wherein the average [sA(t)] calculates the average value of signal sA(t) from 0 time-point to tPAT time-point.

sB′(t)=sB(t)−average[sB(t)] (2)
wherein the average [sB(t)] calculates the average value of signal sB(t) from 0 time-point to tPAT time-point.

The averaging of the signal sA(t) or sB(t) is done in order to determine the constant value of the signal sA(t) or sB(t).

A full cross-correlation R(t′) between the signals sA(t) and sB(t) is afterwards calculated by the measuring instrument 24 as shown below.

R(t′)=1/(2*tPAT)*∫sA′(t)*sB′(t+t′)dt (3)
for an integration over the value of t from −tPAT to tPAT.

The graph 35 of the full cross-correlation R(t′) is illustrated in FIG. 4. The full cross-correlation R(t′) can be interpreted as showing a measure or a degree of alikeness between the signal sA(t) and the signal sB(t+t′). The degree of alikeness is at its highest point or its maximum if t′=−tDEL, wherein there is no delay between the signal sA(t) and the signal sB(t+t′). A degree of alikeness over displacement is calculated here.

The signal sB(t+t′) is then obtained from the signal sB(t) by shifting it forward in time by t′ time. In the example, the value of t′ comprises a negative value. The signal sB(t+t′) is derived from the signal sB(t) by shifting it backward in time. Moreover, polarity of the tDEL may be used to determine the direction of the signal, in this example.

The above described method applies for analog signals sA(t) and sB(t).

In a further embodiment, digital methods are applied.

The signals sA(t) and sB(t) may therefore—according to step 11 of FIG. 1—be digitized or sampled by the measuring instrument 24 for digital calculating in which the signals sA(t) and sB(t) are replaced by digitized signal vectors sA(n) and sB(n) respectively. In a special example, the signal is sampled by the measuring instrument 24 to obtain the digitized signal vectors sA(n) and sB(n).

The signal sA(t) and sB(t) are assumed to have already been treated in order to remove constant value components.

The number n represents a sample number. The signal vectors sA(t) and sB(t) are sampled at intervals of T time.

The equation of full cross correlation vector R(m) of the digitized signal vectors sA(n) and sB(n) is then—according to step 12 of FIG. 1—calculated by the measuring instrument 24 as:

R(m)=ΣsA(n)*sB(n+m) (4)
for summation over the value of n from −nPAT to nPAT wherein the value of n is an integer of (t/T) and the value of nPAT is an integer of (tPAT/T).

For simplicity purpose, the scaling factor of 1/(2*tPAT) has been omitted from the above calculation.

Inferring from equation (4), the digitized signal vectors sA(n) and sB(n) comprise a nPAT number of samples and the full cross-correlation vector R(m) comprises (2*nPAT-1) number of samples. So the length of a full cross-correlation vector R(m) is almost twice as long as the number of samples taken.

A degree of alikeness over displacement m between sA(n) and sB(n) is calculated here.

In a special embodiment, the digitized signal vector sA(n) is equal to s1(n) and the digitized signal vector sB(n) is equal to s1(n+nDEL). This is the case if there is no degradation of the transmitted signal in the transmission line. The digitized signal vector sB(n) is identical to the digitized signal vector sA(n) except for an offset of nDEL number of samples. The full cross correlation vector R(m) of the digitized signal vectors sA(n) and sB(n) is afterwards calculated. In this theoretical case, the full cross-correlation vector R(m) becomes simple.

R(m)=Σs1(n)*s1(n+nDEL+m) (5)
for summation over the value of n from −nPAT to nPAT

The value of the full cross correlation vector R(m) reaches a maximum if m=−nDEL which occurs when sB(n) is shifted by nDEL number of samples.

The above embodiments illustrate the steps of the analog and digital methods to determine the direction of signal transmission of a unidirectional communication system 20. The methods have the advantage that they do not necessarily require a controlled environment in a form of an automated test environment (ATE) in order to determine the direction of the signal transmission. The methods can be applied in an end-user application environment. Moreover, the methods do not necessarily require the communication system to provide a directional signal indicator such as a command signal.

This example illustrates a unidirectional communication system for better understanding of the application. In practice, the method can also be applied to a bidirectional system.

In a generic sense, the method comprises a step of obtaining signals and a step of processing the signal traces. The step of obtaining the signals may be performed by a measuring instrument whilst the step of processing the signals may be performed by the measuring instrument. In another example, the step of processing can be performed by a separate calculating unit. The step of processing may also be executed in a dedicated hardware, for example a semiconductor device that may or may not be built into an application.

The method may be programmed in a form that can be executed by a computer or a calculating unit. A computer program may perform the steps of the method. The computer program may be stored in a data carrier such as memory storage devices or in a medium that is readable by the computer.

In the following description, digital methods are applied. Signal vectors are obtained by digitizing signal traces. The signal vectors are then processed with digital means. This does not mean that the examples are limited to digital methods. Similar results can be obtained using analog methods. Therefore, in the further description, the expression signals stands for analog signals as well as for digital signal vectors.

FIGS. 5 to 7 illustrates a further embodiment of a method to determine a direction of a signal transmission.

FIG. 5 illustrates a bidirectional communication system 40, which includes a transmission line 41, a first transmitter 42, a first receiver 43, a second transmitter 44, a second receiver 45 and a measuring instrument 48.

The transmission line 41 includes a first end and a second end. The first end is coupled to the first transmitter 42 and the first receiver 43 whilst the second end is coupled to the second transmitter 44 and the second receiver 45.

A third signal observation point (C) 46 is chosen at a first section of the transmission line 41 whilst a fourth signal observation point (D) 47 is chosen at the second section of the transmission line 41.

The measuring instrument 48 includes a plurality of inputs 52 and 53 and a plurality of outputs 58 and 59. The input 52 is coupled to the third signal observation point (C) 46 via a probe 56 whilst the input 53 is coupled to the fourth signal observation point (D) 47 by a probe 57.

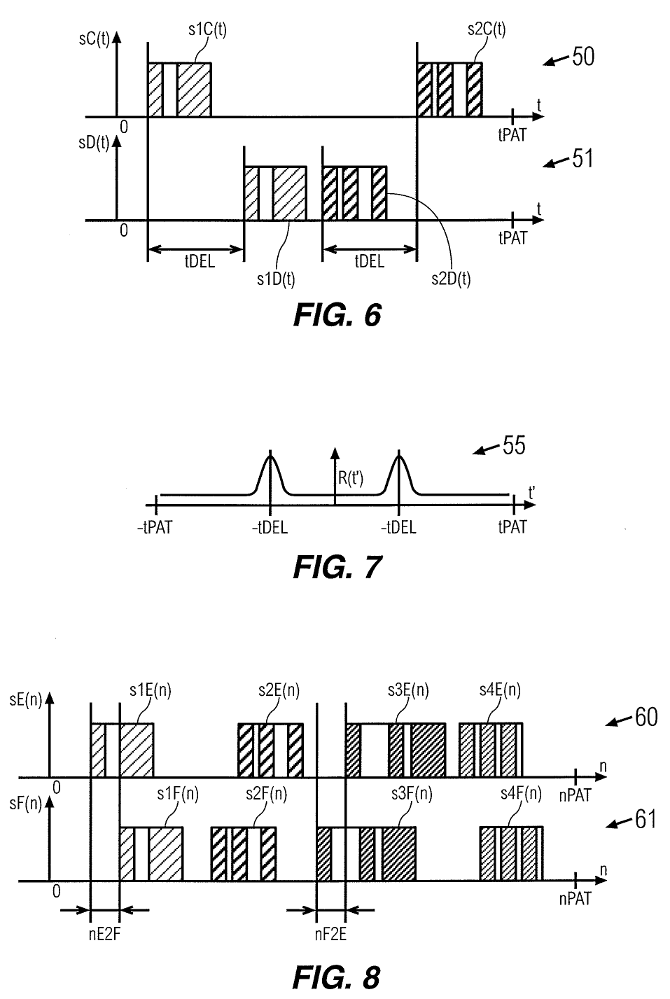

FIG. 6 illustrates graphs of signals of the bidirectional communication system 40 of FIG. 5 as observed by the measuring instrument 48. The FIG. 6 shows a third signal graph 50 and a fourth signal graph 51.

The third signal 50 includes a signal sC(t) taken at the third signal observation point (C) 46. The signal sC(t) extends from 0 time-point to tPat time-point. The signal sC(t) includes signals s1C(t) and s2C(t). In contrast, the fourth signal 51 comprises a signal sD(t) taken at the fourth signal observation point (D) 47 extending from 0 time-point to tPat time-point. The signal sD(t) includes signals s1D(t) and s1D(t).

The shape of the signal s1C(t) is similar to the shape of the signal s1D(t). Relative to the signal s1C(t), the signal s1D(t) as provided is delayed by a delay time of tDEL. Thus, the signals s1C(t) and s1D(t) are essentially identical and include a time shift tDEL.

The shape of the signal s2C(t) is similar to the shape of the signal s2D(t). Relative to the signal s2D(t), the signal s2C(t) as provided is delayed by a delay time of tDEL. Hence, the signals s2C(t) and s2D(t) are essentially identical and comprise a time shift tDEL.

FIG. 7 illustrates a full cross-correlation graph R 55 of the signals sC(t) and sD(t) of FIG. 6. The full cross-correlation graph R 55 extends from −tPAT time-point to tPAT time-point. The full cross-correlation graph R 55 includes a flat horizontal line with two peaks, which are placed at the −tDEL time-point and at the tDEL time point.

The values of the two peaks can vary or can be same. Their values are proportional to a read and write direction density.

In a generic sense, the first transmitter 42, as provided here, is for sending a signal to the second receiver 45 whilst the second transmitter 44, as provided here, is for sending a signal to the first receiver 43. The third signal observation point (C) 46, as provided here, is for observing the signals whilst the fourth observation point (D) 47, as provided here, is for observing the signals. The transmission line 41, as provided here, acts as a conduit for the transmission of the signals between the first transmitter 42 and the second receiver 45 and between the second transmitter 44 and the first receiver 43. The measuring instrument 48, as provided here, receives signals via probes 54, processes these signals, and sends the processed signals to the output 53 of the measuring instrument 24. The processed signals can be in a form of a full cross-correlation R of signals or in a form of a direction function M of the full cross-correlation R.

An embodiment of the method to determine transmission directions of signals of a bidirectional communication system 40 comprises obtaining signal readings or signals from two different positions or observation points of the transmission line 41 by the measuring instrument 48. The signal sC(t) is observed at the third signal observation point (C) 46 whilst the signal sD(t) is observed at the fourth signal observation point (D) 47, as illustrated in the FIGS. 5 and 6.

A signal sent from the first transmitter 42 to the second receiver 45 is observed as signal s1C(t) at the third signal observation point (C) 46 and as signal s1D(t) at the fourth signal observation point (D) 47. A signal sent from the second transmitter 44 to the first receiver 43 is observed as signal s2C(t) at the third signal observation point (C) 46 and as the signal s2D(t) at the fourth signal observation point (D) 47. This is illustrated in FIG. 6. The graph of the full cross-correlation R(t′) of the signals sC(t) and sD(t) is illustrated in FIG. 7.

In a digital method and according to step 11 of FIG. 1, the signals sC(t) and sD(t) are sampled by the measuring instrument 48 in order to form digitized signal vectors sC(n) and sD(n) respectively. In a further example, the digitized signal vectors sC(n) is formed from sampling the signals at the third signal observation point (C) 46 whilst the digitized signal vectors sD(n) is formed from sampling the signals at the fourth signal observation point (D) 47.

According to step 12 of FIG. 1, a full cross-correlation vector R(m) of the digitized signal vectors sC(n) and sD(n) is afterwards calculated by the measuring instrument 48 in a manner similar to the method of the embodiment illustrated by the FIGS. 2 to 4.

R(m)=ΣsC(n)*sD(n+m) (6)
for summation over value of n from −nPAT to nPAT,
wherein the value of n is an integer of (t/T) and the value of nPAT is an integer of (tPAT/T), and T is a period of the sampling rate.

The full cross-correlation vector R(m) can be interpreted as measuring a degree of alikeness between the digitized signal vector sC(n) and the shifted digitized signal vector sD(n+m). A degree of alikeness over displacement m between sC(n) and sD(n) is calculated here.

As one can infer from FIG. 7 and equation (6), the full cross-correlation vector R(m) comprises two peaks. The peaks are located at nDEL sample number and at the −nDEL sample number, where the value of nDEL is the integer of (tDEL/T).

The peak that is placed at the −nDEL sample number occurs when the degree of alikeness between the digitized signal vector sC(n) and a shifted digitized signal vector sD(n+m) that is sent from the first transmitter 42 to the second receiver 45 reaches a peak value.

The nDEL sample number is a form of n12 sample number, which represents a travelling time of a signal from the third signal observation point (C) 46 to the fourth signal observation point (D) 47.

Similarly, the peak that is placed at the +nDEL sample number occurs if there is the degree of alikeness between the signal vector sC(n) and a shifted signal vector sD(n+m) that is sent from the second transmitter 44 to the first receiver 43 reaches a peak value.

The +nDEL sample number is a form of n21 sample number, which represents a travelling time of a signal from the fourth signal observation point (D) 47 to the third signal observation point (C) 46.

The value of the −n12 in the form of −nDEL and the value of n21 in the form of +nDEL sample numbers can be determined from the full cross-correlation graph R 55 of FIG. 7. In a generic sense, the n12 sample number may be different from the n21 sample number.

In a further example of the application, the signal sent from the first transmitter 42 to the second receiver 45 may represent a read signal and the signal sent from the second transmitter 44 to the first receiver 43 may represent a write signal.

According to step 13 of FIG. 1, a moving cross-correlation with window function vector K12(m) that measures a degree of alikeness of a signal that is sent from the first transmitter 42 to the second receiver 45 is then calculated by the measuring instrument 48.

Similarly, a moving cross-correlation with window function vector K21(m) that measures a degree of alikeness of a signal that is sent from the second transmitter 44 to the first receiver 43 is then calculated by the measuring instrument 48.

A direction function vector M(m) then calculated by the measuring instrument 48 where

M(m)=K12(m)−K21(m) (9)

The calculated values of the direction function vector M(m) is later sent to the output 58. The values of the direction function vector M(m) provides an indication of the direction of the signal.

When the value of the direction function vector M(m) is greater than 0, the signal can be interpreted as being sent from the first transmitter 42 to the second receiver 45. The value of the direction function vector M(m) is greater than 0 when the degree of alikeness of a signal that is sent from the first transmitter 42 to the second receiver 45 is greater than the degree of alikeness of a signal that is sent from the second transmitter 44 to the first receiver 43.

Similarly, if the value of the direction function vector M(m) is less than 0, the signal can be interpreted as being sent from the second transmitter 44 to the first receiver 43. The value of the direction function vector M(m) is less than 0 if the degree of alikeness of a signal sent from the first transmitter 42 to the second receiver 45 is less than the degree of alikeness of a signal that is sent from the second transmitter 44 to the first receiver 43.

Based on the direction vector function M(m), a signal in the transmission line can afterwards be categorised into portions of the signal that is sent in one direction and into portions of the signal that is sent in the other direction.

The above steps will later be explained in greater detail with reference to the embodiment of FIG. 8-10.

The method may include a further step of filtering the values of the direction vector function M(m) by the measuring instrument 48. The filtering may replace values of the direction vector function M(m) that are greater than a pre-determined value with a pre-determined constant. The filtering may also act as a low pass filter to remove high frequency components of the direction vector function M(m).

For interpreting the embodiment illustrated in FIGS. 5 to 7 one may also, by way of reference, refer to the explanations and remarks stated above with respect to the embodiment that is illustrated in FIGS. 2 to 4 where appropriate.

The step of categorising parts of a signal in the transmission line into parts that are sent in one direction from parts that are sent in the other direction provides advantages in the area of analysis. Abnormal signal characteristic that is present in only one particular direction of signal transmission can be easily identified through the step of categorising.

FIGS. 8 to 10 illustrate a further embodiment of the method. FIG. 8 shows digitized signals 60 and 61 of the bidirectional communication system 40 of FIG. 5.

FIG. 8 shows a fifth digitized signal 60 of the third signal observation point (C) 46 and a sixth digitized signal graph 61 of the fourth signal observation point (D) 47 as observed by the measuring instrument 48 of FIG. 5.

The fifth digitized signal 60 shows a digitized signal vector sE(n) over sample number, and it extends from 1 sample number to nPAT sample number. The digitized signal vector sE(n) comprises digitized signal vectors s1E(n), s2E(n), s3E(n), and s4E(n).

Similarly, the sixth digitized signal graph 61 shows a digitized signal vector sF(n) over sample number. The sixth digitized signal graph extends from 1 sample number to nPAT sample number. The digitized signal vector sF(n) includes digitized signal vectors s1F(n), s2F(n), s3F(n), and s4F(n).

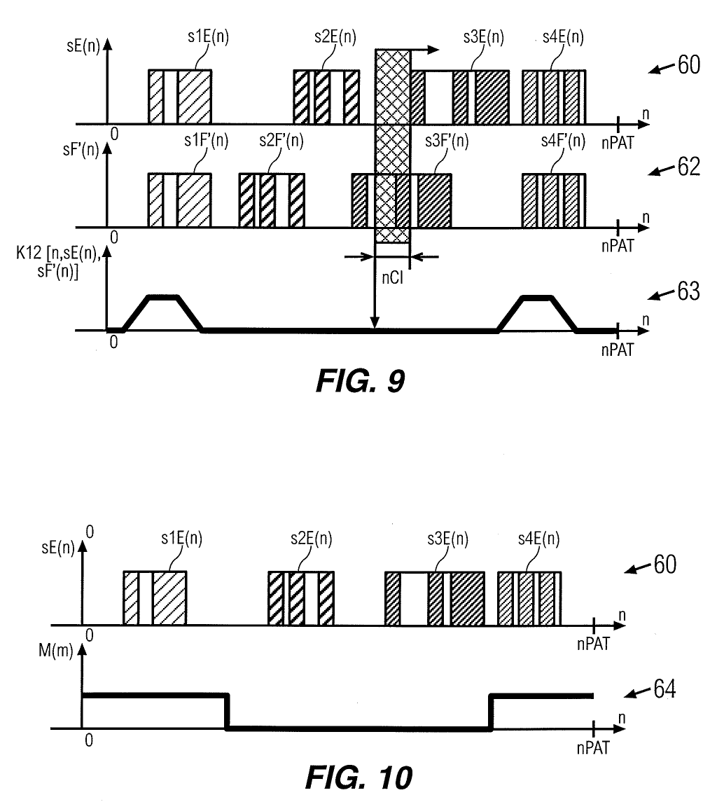

FIG. 9 illustrates the fifth digitized signal 60 of FIG. 8, a modified digitized signal graph 62, and a moving cross correlation with window graph K 63.

The modified digitized signal graph 62 shows a modified digitized signal vector sF′(n) over sample number and it extends from 1 sample number to nPAT sample number. The modified digitized signal vector sF′(n) includes modified digitized signal vectors s1F′(n), s2F′(n), s3F′(n), and s4F′(n).

The moving correlation with window graph K 63 includes a moving cross correlation with window vector K12 [n, sE(n), sF′(n)] of the digitized signal vector sE(n) and the modified digitized signal vector sF′(n).

FIG. 10 illustrates the fifth digitized signal 60 of FIG. 8 and a graph of direction function M(m), which shows a high value across the sample numbers where the digitized signal vectors s1E(n) and s4E(n) are present, indicating their transmission direction. The direction function M(m) indicates that s1E and s4E are transmitted from transmitter 42 to receiver 45 and that s2E and s3E are transmitted from 44 to 43.

An embodiment of the method to determine a transmission direction of signals of a bidirectional communication system 40 of FIG. 5 by the measuring instrument 48 comprises—according to step 11 of FIG. 1—the step of obtaining digitized signal vectors sE(n) and sF(n) from two different positions of the transmission line 41 by the measuring instrument 48, as illustrated in FIG. 8.

The delay times between the digitized signal vectors sE(n) and sF(n) is then determined according to step 12 of FIG. 1. A signal that is sent from the first transmitter 42 to the second receiver 45 has delay of nE2F number of samples. The step of determining the delay is similar to the step shown in the earlier embodiment, using a full cross-correlation R(m) as a means for determining delay time by degree of alikeness. A degree of alikeness over displacement is calculated here.

A modified digitized signal-trace vector sF′(n) is expressed as:

sF′(n)=sF(n−nE2F) (10)

As one can see from equation (10), the modified signal vector sF′(n) is obtained from the digitized signal vector sF(n) by shifting the digitized signal vector SF(n) earlier by nE2F number of samples.

According to step 13 of FIG. 1, a moving cross correlation with window vector K12(m) is expressed as:

K12(m)=ΣsE(n+m)*sF′(n+m) (11)
for summation over the value of n that is from 1 to nCI.

The constant nCI is a summation interval or correlation interval of the window. The correlation interval nCI is the amount of signal—in terms of samples—that is used to calculate the moving cross correlation vector K12(m). For a number n of 1000 samples, a value of nCI may be chosen as 50.

The value m is a variable, which runs from 1 to (nPAT+nCI−1), so for a number n of 1000 samples, m is running from 1 to 1049, if a value of nCI is chosen as 50.

The moving cross correlation with window vector K12(m) can be interpreted as showing a degree of an alikeness of the digitized signal vector sE(n+m) to the modified digitized signal vector sF′(n+m) for a signal that is send from the first transmitter 42 to the second receiver 45. A degree of alikeness over time is calculated here. The degree of alikeness is measured within the correlation interval nCI of the window, as illustrated in FIG. 9.

Similarly, a moving cross correlation with window vector K21(m) measures a degree of an alikeness of the digitized signal vector sE(n) to the modified digitized signal vector sF″(n) for a signal that is send from the second transmitter 44 to the first receiver 43.

The moving cross correlation with window vector K21(m) is:

sF′(n)=sF(n+nF2E) (12)
where nF2E sample number equals delay in sample number
for the signal being sent from the second transmitter 44 to the first receiver 43.

K21(m)=ΣsE(n+m)*sF″(n+m) (13)
for summation over value of n from 1 to nCI.

After this, the signal direction function vector M(m) is calculated by the measuring instrument 48.

M(m)=K12(m)−K21(m) (14)

The interpretation of the signal direction function vector M(m) is similar to the one described in the earlier embodiment.

The method may include a further step of filtering the values of the direction function vector M(m) in a manner described for the earlier embodiment.

For interpreting the embodiment illustrated in FIGS. 8 to 10 one may also, by way of reference, refer to the explanations and remarks stated above with respect to the embodiments which are illustrated in FIGS. 2 to 4 and FIGS. 5 to 7, where appropriate.

The moving cross correlation with window vector K12(m) or K21(m) has the advantage in that the samples taken in order to calculate the cross correlation with window vector K12(m) or K21(m) is more related or even confined to the samples within the window. The calculation may ignore samples outside of the window which may include irregular samples generated by noise that would distort the computational value of the cross correlation with window vector K12(m) or K21(m).

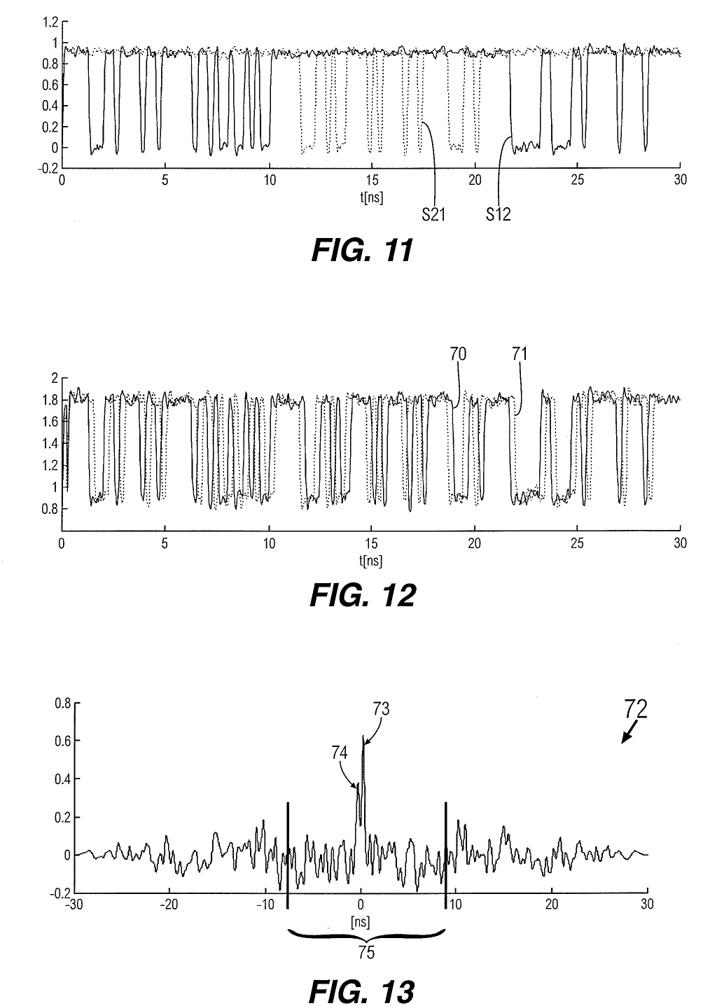

FIGS. 11 to 16 illustrates an embodiment of further method of use. FIG. 11 shows graphs of signals S12 and S21 of the bidirectional communication system 40 of FIG. 5.

The signal S12 is sent by the first transmitter 42 and received by the second receiver 45 whilst the signal S21 is sent by the second transmitter 44 and received by the first receiver 43.

FIG. 12 illustrates graphs of further signal 70 and 71 of the bidirectional communication system of FIG. 5. The signal 70 is superimposed on the signal 71.

FIG. 12 shows a seventh signal 70 taken at the third signal observation point (C) 46 and a eighth signal 71 taken at the fourth signal observation point (D) 47 by the measuring instrument 48 of FIG. 5.

The shape of seventh signal 70 is similar to the shape of the eighth signal 71. The seventh signal 70 comprises parts that are slightly ahead in time of parts of the eighth signal 71, and other parts that are slightly behind in time of other parts of the eighth signal 71.

FIG. 13 illustrates a full cross-correlation graph R 72 of the signals 70 and 71 of FIG. 12. An alikeness over displacement is calculated here.

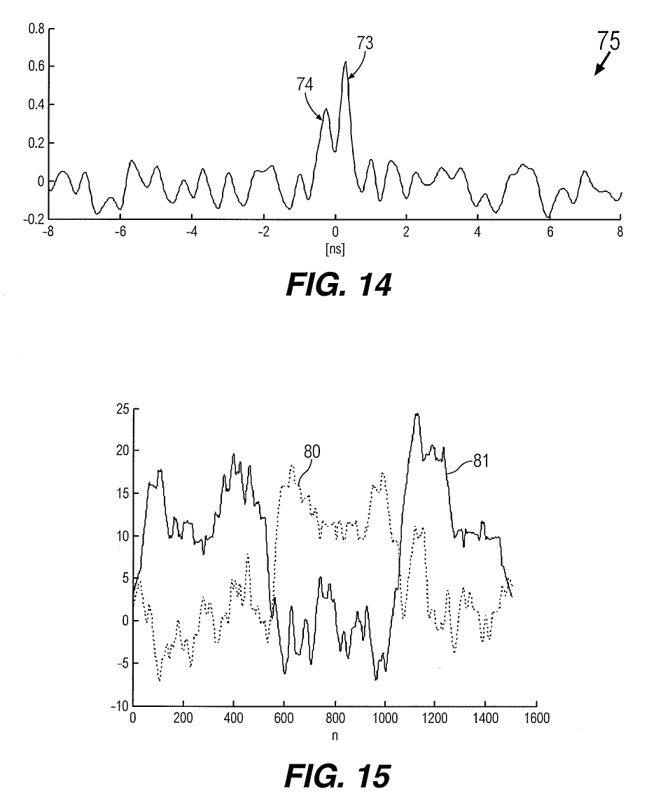

The full cross-correlation graph R 72 includes two peaks 73 and 74. FIG. 14 illustrates a zoomed view 75 of the full cross-correlation graph R of FIG. 13 for easy viewing.

The two peaks 73 and 74 are placed near the 0 time-point of the graph 72. The peak 73 is placed at a positive time point whilst the peak 74 is placed at a negative time point. The peaks 73 and 74 are at about equal distances away from the 0 time point.

FIG. 15 illustrates moving cross-correlation with window graphs K 80 and 81 of the signals 70 and 71 of FIG. 12.

The time axis here shows “number of samples n” with a given sample rate of 1500 samples per sampling time of 30 nsec (nanoseconds). This is equivalent to a sample rate of 50 GSps (Giga-sample per second).

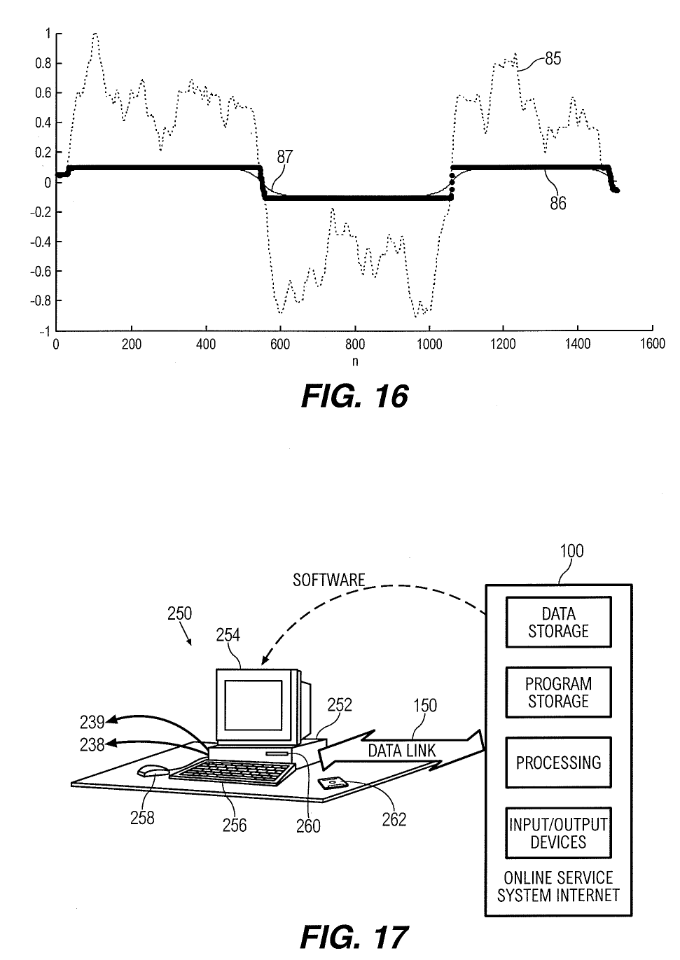

FIG. 16 illustrates direction function graphs M 85, 86 and 87 of the signals 70 and 71 of FIG. 11. The direction function M=K12−K21 has a high degree of information because it expresses which one of the two degrees of alikeness over time is greater. From this it can be found out whether the given window is more alike to “writing” or to “reading”.

The direction function graph M 85 shows a graph of direction function M of the signals 70 and 71. The direction function graph M 86 shows the direction function graph M 85 that is filtered in order to limit its upper and lower maximum value. The direction function graph M 87 shows the direction function of graph M 86 that is filtered in order to remove its high frequency components.

The example of the method to determine a transmission direction of signals of a bidirectional communication system 40 of FIG. 5 comprises—according to step 11 of FIG. 1—the step of obtaining the signals 70 and 71 from the signals S112 and S21 by the measuring instrument 48. The signals S12 and S21 are illustrated in FIG. 11 whilst the signals 70 and 71 are illustrated in FIG. 12.

The signals 70 and 71 are then sampled to form digitized signal vectors.

The full cross correlation vector R(m) the digitalized signal vectors is afterward calculated in a manner described in the above embodiment. The full cross correlation vector R(m) is illustrated in FIGS. 13 and 14.

The delay times of the signals 70 and 71 are then calculated from the full cross correlation vector R(m), according to step 12 of FIG. 1. The peaks 73 and 74 of FIG. 13 or 14 illustrates where delay times of the digitized signal 70 and 71 are found.

The step of determining direction function M is then performed in accordance to step 13 of FIG. 1. The moving cross-correlations with window K of the digitized signals are calculated in a manner described in the above embodiment. The moving cross-correlations with window K are shown in FIG. 15.

The direction function M is afterwards derived from the moving cross-correlations with window K in a manner described in the above embodiment. The direction function M is illustrated in FIG. 16. The direction function M may be filtered to enhance robustness of the method against noise and jitter on the sampled signals. The filtered direction functions M are also shown in FIG. 16.

FIG. 17 schematically shows an embodiment of a customer computer 250 accessing an on-line service system 100.

The customer computer 250 may for example be a standard personal computer including a main processor unit 252, a display 254, a keyboard 256, and a mouse 258. Main processing unit 252 typically includes a floppy disk slot drive 260 that reads floppy diskettes 262.

Customer computer 250 performs tasks for a user under software control, and displays the results of the tasks on display 254. An optional printer can be connected to main processing unit 252 in order to print out the results.

New software can be loaded onto customer computer 250 by storing the software on floppy diskette 262 and inserting the floppy diskette 262 into disk slot 260 so that it can be read by the main processor unit 252. The user operates keyboard 256 and mouse 258 to interact with the software tasks performed by computer 250.

Customer computer 250 as described above is a self-contained, stand-alone unit that is capable of performing a wide variety of processing tasks without having to be connected to any other computer equipment.

Depending upon the software loaded into main processor unit 252, the user may be able to perform a wide variety of additional software tasks such as, for example, video games, check book management, graphics generation program, etc. The variety of different tasks customer computer 250 is capable of performing is determined by the availability of software needed to perform the tasks.

The customer computer 250 connects to an on-line service system 100 provided by the preferred embodiment of the present invention via a data link 150 as shown in FIG. 17. The data link 150 may comprise a dial up telephone line or other similarly convenient telecommunications link that allows customer computer 250 to be located remotely to the on-line service system 100. The on-line service system 100 provides various capabilities that enhance the operations of customer computer 250. The on-line service system 100 provides software and computing services to customer computer 250. Such software provides the operation of the customer computer 250 as a measuring instrument.

The customer computer 250 has a probe line 238 and a probe line 239, the probe line 238 and the probe line 239 being connected to an analog-digital converter card being provided in the customer computer 250.

The customer computer 250 is programmed to execute a method such as described in one of the above-mentioned embodiments. Calculations may then be done by computing the relevant equations.

The floppy diskette 262 as a data carrier contains a computer program product to execute a method such as described in one of the above-mentioned embodiments. The computer program product may be carried in a computer-readable medium. The computer program and the computer program product can also be downloaded from the Internet. Customer computer 250 is programmed to execute the instructions within in the computer program product.

In another embodiment, the computer program product to execute a method such as described in one of the above-mentioned embodiments is downloaded from the data link 150.

Although the above description contains much specificity, these should not be construed as limiting the scope of the embodiments but merely providing illustration of the foreseeable embodiments. Especially the above stated advantages of the embodiments should not be construed as limiting the scope of the embodiments but merely to explain possible achievements if the described embodiments are put into practise. Thus, the scope of the embodiments should be determined by the claims and their equivalents, rather than by the embodiments given.

What is claimed is:

1. A method that comprises the step of
obtaining a first signal trace sa(t) of a signal from a first position of a transmission channel, and a second signal trace sb(t) of the signal from a second position of the transmission channel, and
determining a delay time between the first signal trace sa(t) and the second signal trace sb(t) of the signal by a full cross-correlation of the first signal trace sa(t) and the second signal trace sb(t).

2. The method of claim 1 that comprises the further step of treating of the first and the second signal traces sa(t) and sb(t), the treating comprises the steps of:
calculating an average [sa(t)], the average [sa(t)] calculates the average value of signal trace sa(t) from 0 time-point to the tPAT time-point, calculating sA(t)=sa(t)−average [sa(t)]
wherein the first signal trace sa(t) extends from 0 time-point to tPAT time-point,
calculating an average [sb(t)], the average [sb(t)] calculates the average value of signal trace [sb(t)] from 0 time-point to the tPAT time-point, and calculating sB(t)=sb(t)−average [sb(t)]
wherein the second signal trace sb(t) extends from 0 time-point to the tPAT time-point.

3. The method of claim 2 wherein
the step of determining delay time comprises calculating of the full cross-correlation R(t′) between the signal traces sA(t) and sB(t), the full cross-correlation R(t′) comprising a calculation of:
R(t′)=∫sA(t)*sB(t+t′)dt
for integration over the value of t from −tPAT to tPAT.

4. A method that comprises
an obtaining step of a first signal trace sA(t) of a signal from a first position of a transmission channel, and a second signal trace sB(t) of the signal from a second position of the transmission channel, and
a determining step of a direction function vector M(m) of the signal by a moving cross correlation with window vector of the first signal trace sA(n) and the second digitized signal trace sB(n) of the signal,
where the step of obtaining comprises sampling of the first signal trace sA(t) to form a first digitized signal vector sA(n), and sampling of the second signal trace sB(t) to form a second digitized signal vector sB(n).

5. The method of claim 4 wherein
the step of determining the delay time comprises calculating of the full cross correlation vector R(m) of the first signal trace sA(n) and the second digitized signal trace sB(n), the full cross correlation R(m) comprising a calculation of:
R(m)=ΣsA(n)*sB(n+m)
for summation over the value of n from −nPAT to nPAT.

6. The method of claim 5 wherein
the step of determining the direction comprises calculating of the moving cross correlation with window vector K12(m), the moving cross correlation with window vector K12(m) comprising a calculation of:
sB′(n)=sB(n+n12)
if a sample number n12 comprises a positive value of m if a maximum value of the full cross correlation vector R(m) is located.
K12(m)=ΣsA(n+m)*sB′(n+m)
for summation over the value of n from 1 to a correlation interval nCI.

7. The method of claim 6 wherein
the step of determining the direction comprises calculating the moving cross correlation with window vector K21(m), the moving cross correlation with window vector K21(m) comprising a calculation of:
sB″(n)=sB(n−n21)
where a sample number n21 comprises a negative value of m where a maximum value of the full cross correlation vector R(m) is located,
K21(m)=ΣsA(n+m)*sB″(n+m)
for summation over value of n from 1 to the correlation interval nCI.

8. The method of claim 7 wherein
the step of determining the direction comprises calculating the direction function vector M(m), the direction function vector M(m) comprising a calculation of:
M(m)=K12(m)−K21(m).

9. A method that comprises the steps of
determining a delay time between digitized signal traces of a signal by a full cross correlation vector of the digitized signal traces, and
determining a direction function vector M(m) of the signal by a moving cross correlation with window vector of the digitized signal traces.

10. A method that comprises the step of
obtaining a first signal trace of the signal from a first position of a transmission channel, and a second signal trace of the signal from a second position of the transmission channel,
determining a delay time between the first signal trace and the second signal trace by a first degree of alikeness of the first signal trace and the second signal trace, and
determining a direction function vector of the signal by a second degree of alikeness of the first signal trace and the second signal trace.

11. An apparatus that comprises:
a measuring instrument with two probes to obtain a first signal trace of a signal from a first position of a transmission channel and a second signal traces of the signal from a second position of the transmission channel,
a calculation unit to determine a delay time between the first and second signal traces by calculating a full cross correlation of the first and second signal traces, and
an output to transmit the direction of the signal.

12. An apparatus that comprises:
a measuring instrument with two probes to obtain a first digitized signal trace of a signal from a first position of a transmission channel and a second digitized signal trace of the signal from a second position of the transmission channel,
a calculation unit to determine a direction of the signal by calculating a moving cross-correlation with window of the first and second digitized signal traces, and an output to transmit the direction of the signal.

13. An apparatus that comprises:
a measuring instrument with two probes to obtain a first digitized signal trace of a signal from a first position of a transmission channel and a second digitized signal trace of the signal from a second position of the transmission channel,
a calculation unit to determine a delay time between the first and second digitized signal traces by calculating a full cross correlation of the first and second digitized signal traces, and to determine a direction of the signal by calculating a moving cross-correlation with window of the first and second digitized signal traces, and an output to transmit the direction of the signal.

14. An apparatus that comprises:
a measuring unit to obtain a first signal trace of a signal from a first position of a transmission channel and a second signal trace of the signal from a second position of the transmission channel,
a calculating unit to determine a delay time between the first signal trace and the second signal trace by calculating a first degree of alikeness of the first signal trace and the second signal trace, and
an output to transmit the delay time between the first signal trace and the second signal trace.

15. An apparatus that comprises:
a measuring unit to obtain a first signal trace of a signal from a first position of a transmission channel and a second signal trace of the signal from a second position of the transmission channel,
a calculating unit to determine a direction function of the signal by calculating a first degree of alikeness of the first signal trace and the second signal trace, and an output to transmit the direction function of the signal.

16. An apparatus that comprises:
a measuring unit to obtain a first signal trace of a signal from a first position of a transmission channel and a second signal trace of the signal from a second position of the transmission channel,
a calculating unit to determine to determine a delay time between the first signal trace and the second signal trace by calculating a first degree of alikeness of the first signal trace and the second signal trace and a direction function of the signal by calculating a second degree of alikeness of the first signal trace and the second signal trace, and
an output to transmit the direction function of the signal.

17. A computer system programmed to execute a method according to claim 4.

18. A computer system programmed to execute a method according to claim 10.

19. A computer program product to execute a method according to claim 4.

20. A computer program product to execute a method according to claim 10.

21. A data carrier with a computer program product according to claim 19.

22. A data carrier with a computer program product according to claim 20.

23. A computer program product according to claim 19 carried in a computer-readable medium.

24. A computer program product according to claim 20 carried in a computer-readable medium.

25. A computer system programmed to execute the instructions within in the computer program product according to claim 19.

26. A computer system programmed to execute the instructions within in the computer program product according to claim 20.
